(19) United States
(12) Patent Application Publication
(10) Pub. No.: US 2008/0144244 A1
(43) Pub. Date: Jun. 19, 2008

(54) WELL POTENTIAL TRIGGERED ESD PROTECTION

(76) Inventor: Benjamin Van Camp, Antwerp (BE)

Correspondence Address: PATENT DOCKET ADMINISTRATOR;LOWENSTEIN SANDLER P.C., 65 LIVINGSTON AVENUE, ROSELAND, NJ, 07068, US

(21) Appl. No.: 11/953,139

(22) Filed: Dec. 10, 2007

Related U.S. Application Data
(60) Provisional application No. 60/869,364, filed on Dec. 11, 2006.

(51) Int. Cl. H02H 9/00; H01L 27/10

(52) U.S. Cl. 361/56; 257/360; 257/E27.07

(57) ABSTRACT

The present invention provides an integrated circuit for providing ESD protection. The integrated circuit comprises a transistor device having at least one interleaved finger having a substrate region, a source, drain and gate region formed over a channel region disposed between the source and the drain regions. The transistor device further comprises at least one highly doped junction formed adjacent to the source region to measure voltage potential of the substrate region. The integrated circuit further comprises a switching circuit coupled to the at least one highly doped junction such that the voltage potential is transferred to the switching circuit to either draw the full ESD current or trigger to draw the full ESD current.

### CROSS REFERENCES

This patent application claims the benefit of U.S. Provisional Application Ser. No. 60/869,364 filed Dec. 11, 2006, the contents of which are incorporated by reference herein.

### FIELD OF THE INVENTION

This invention generally relates to the field of electrostatic discharge (ESD) protection circuitry, and more specifically, for providing improvements for output protection. The invention also helps to protect core transistors in case of Charged Device Model (CDM) stress cases or similar stresses.

### BACKGROUND OF THE INVENTION

Integrated circuits (ICs) and other semiconductor devices are extremely sensitive to the high voltages that may be generated by contact with an ESD event. As such, electrostatic discharge (ESD) protection circuitry is essential for integrated circuits. An ESD event commonly results from the discharge of a high voltage potential (typically, several kilovolts) and leads to pulses of high current (several amperes) of a short duration (typically, 100 nanoseconds). An ESD event is generated within an IC, illustratively, by human contact with the leads of the IC or by electrically charged machinery being discharged in other leads of an IC. During installation of integrated circuits into products, these electrostatic discharges may destroy or impair the function of the ICs and thus require expensive repairs on the products, which could have been avoided by providing a mechanism for dissipation of the electrostatic discharge to which the IC may have been subjected. To simulate an ESD event during which the chip is grounded, three models are currently in use. Human Body Model (HBM) and Machine Model (MM) are 2 pin tests (one pin grounded while another pin is positively or negatively stressed). When the IC itself is charged, discharge can happen through one pin. This type of stress is modeled in the Charged Device Model (CDM).

To protect an IC against ESD, specific protection circuits are added on chip. All circuitry which is directly coupled to a bond pad, must be able to sustain a limited amount of ESD stress. Therefore, these pads have an ESD protection circuitry attached to it. But also within the core of the IC ESD failures are possible. Specifically, input and output pins need additional protection, since these circuits are connected to bond pads. Note that the same bond pad can be used to connect an input, such that the same protection could be used to protect both input and output.

In prior art, different ways of protection an output against ESD are proposed. In a first case, the output is made self-protective. This often comes with the drawback of a severely increased area for the driver, since dummy fingers need to be added to handle all ESD current. Furthermore, in most technologies, ballasting needs to be added at drain and/or source side, again increasing the needed area, as well as increasing the on-resistance. In some technologies, this approach is not possible, since the driver is inherently weak for ESD current.

In a second case, a dual diode approach is used, sometimes in combination with a circuit to keep the driver in off state during ESD. The ESD current is redirected through one of the diodes and the power clamp, such that the driver is kept safe. In this case, the driver can be kept fully silicided (i.e. no ballasting is applied) and minimum size (i.e. the size required for normal operation). The main benefit of this solution is that it is minimum in size, however, the trigger requirements for the power clamp are very stringent, since the trigger voltage must be very low to protect the driver.

In a third solution, the first and second cases are combined. In this case, an isolation resistor is placed, while the driver is made robust to handle part of the ESD current, in most cases meaning that ballasting is added, and sometimes also dummy fingers are added. The isolation resistor is calculated such that the power clamp can trigger at a higher voltage by allowing some voltage built up over the resistor during ESD.

As a fourth solution a local protection is added. This local protection (as is the case for the power clamp) can be either a voltage, a RC or current triggered. Again the difficulty in this case is to have the clamp trigger at low enough voltage.

Thus, a need exists in the art to overcome the disadvantages of the prior art to provide an improved output protection for ESD circuitry.

### SUMMARY OF THE INVENTION

In one embodiment of the present invention, there is provided an electrostatic discharge (ESD) protection circuit. The circuit comprises a substrate region having a lightly doped region of the first conductivity type and at least one interleaved finger formed on the substrate region. The at least one interleaved finger comprising at least one source region of a second conductivity type, at least one drain region of the second conductivity type and at least one gate region formed over a channel region disposed between the source and the drain regions. The circuit further comprises at least one highly doped junction of the first conductivity type formed adjacent to the source region of the at least one the interleaved finger. The at least one highly doped junction function to measure potential of the substrate region.

In another embodiment of the present invention, there is provided an integrated circuit for providing ESD protection. The circuit comprises a MOS transistor having a substrate region comprising a lightly doped region of the first conductivity type, at least one interleaved finger formed on said substrate region. The at least one interleaved finger comprising at least one source region of a second conductivity type, at least one drain region of the second conductivity type and at least one gate region formed over a channel region disposed between the source and the drain regions. The circuit also comprises at least one highly doped junction of the first conductivity type formed adjacent to the source region of the at least one the interleaved finger. The at least one highly doped junction function to measure voltage potential of the substrate region. The circuit further comprises a switching circuit connected to the at least one highly doped junction to receive the voltage potential for triggering.

### BRIEF DESCRIPTION OF THE DRAWINGS

FIG. 1A illustrates a cross-section diagram of the ESD protection circuitry in accordance with one embodiment of the present invention.

FIG. 1B illustrates a schematic circuit diagram of the transistor of FIG. 1A.

FIG. 2A through FIG. 2C illustrate different implementations of ESD protecting circuitry using the well potential measuring junction of FIGS. 1A and 1B for multi-finger devices.

FIG. 3A illustrates a block diagram using the ESD protection circuitry of FIGS. 1A and 1B with addition of a switching circuit in accordance with another embodiment of the present invention.

FIGS. 3B and 3C illustrate a schematic representation of a circuit diagram of the block diagram of FIG. 3A in accordance with alternate embodiments of the present invention.

FIG. 4A illustrates a block diagram using the ESD protection circuitry of FIG. 3A with addition of potential transfer circuit in accordance with an additional embodiment of the present invention.

FIG. 4B illustrates a schematic representation of a circuit diagram of the block diagram of FIG. 4A in accordance with an alternate embodiment of the present invention.

FIG. 5A illustrates a block diagram of using the ESD protection circuitry of FIG. 4A with addition of voltage shifter in accordance with another additional embodiment of the present invention.

FIG. 5B illustrates a schematic representation of a circuit diagram of the block diagram of FIG. 5A in accordance with an alternate embodiment of the present invention.

FIG. 6 illustrates a schematic representation of a circuit diagram of the block diagram of FIG. 5A with additional elements in accordance with an alternate embodiment of the present invention

### DETAILED DESCRIPTION OF THE INVENTION

The present invention relates to the protection of the output node. More specifically, the present invention proposes means to use the well potential to trigger the ESD protection. Note that ‘well’ can mean Nwell, Pwell, bulk, body, substrate, or any other layer which is of low enough doping such that a transistor can be build within this layer. Also, note that although most of the embodiments and figures of the present invention describes the invention for an NMOS in a CMOS bulk technology using P-substrate, however, the invention is not limited to this case. Anyone skilled in the art can easily translate the description to the PMOS case and also the use of the invention in other technologies (SOI, multiple well technologies, high voltage etc.) is possible. Furthermore, although in the present invention, the assumption is made that the transistor to be protected is in the periphery of the chip, core transistor can also be protected using the means disclosed herein.

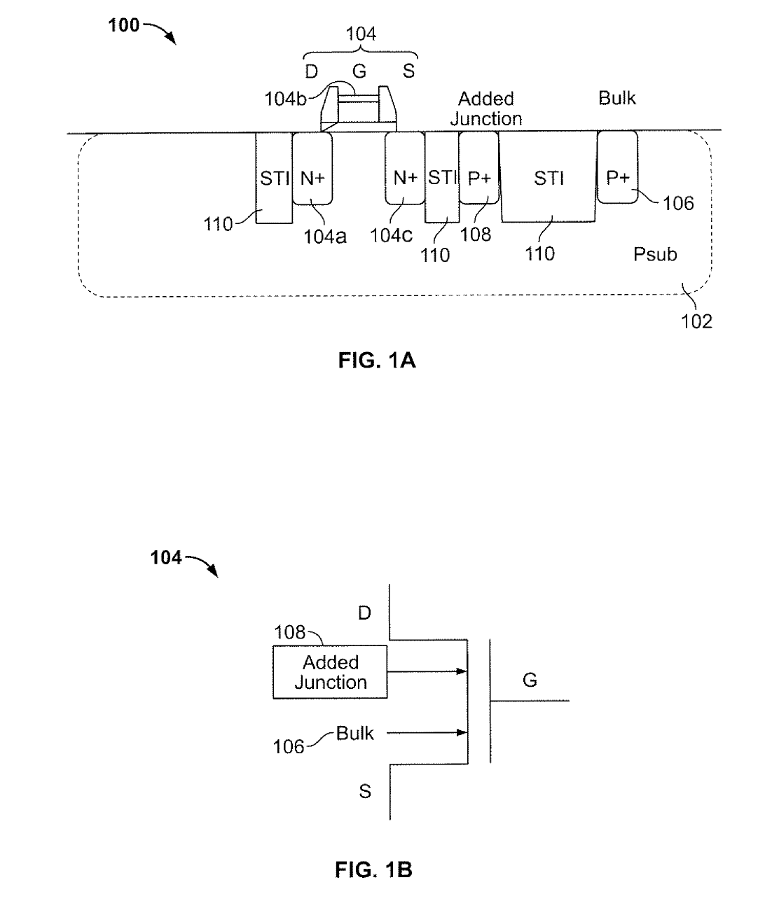

Referring to FIG. 1A, there is shown a cross-section diagram of the ESD protection circuit 100 for providing ESD protection in accordance with one embodiment of the present invention. The circuit 100 comprises a lightly doped region, preferably a P-substrate 102 of first conductivity type. The circuit 100 further comprises a semiconductor device 104 such as a transistor, an exemplary MOSFET in the P-substrate 102 as shown. The transistor 104 preferably comprises a first heavily doped region of a second conductivity type N+ 104a, (drain), a second heavily doped region of the second conductivity type N+ 104b (source) and a gate 104c. Typically, a bulk region 106, preferably having a heavily doped region of the first conductivity type P+, is preferably connected to either the source 104b (FIG. 1B) or to ground (not shown). The circuit 100 further comprises a junction (a.k.a. added junction) 108, preferably having a heavily doped region of the first conductivity type P+, is added in the P-substrate 102 to be able to measure the potential within said P-substrate as illustrated iii. FIGS. 1A & 1B.

Note that the highly doped region 108 is also preferably added to avoid creating a schottky diode when placing a contact. Typically, the process design rules forbid placement of contact directly in the substrate 102 (i.e. without addition of the highly doped region). However, if this is not the case for a given technology, the contact can be placed directly in the well without the highly doped region.

Note that the source 104b of the resistor and the added junction 108 must be electrically isolated by placing an isolation 110 in between. The isolation 110 may preferably be formed by allowing formation of shallow trench isolations (STI), or deep trench isolations (DTI) or even partial trench isolations (PTI) between source 104b and the added junction 108. Alternatively, it may be formed by silicide block (SB), in case of silicided processes, or placing a Poly gate between source 104b and the added junction 108. Similarly, the isolation 110 between the added junction 108 and the bulk region 106 to control the bulk resistance can be formed by using STI, DTI, PTI, SB or Poly.

Amongst others, some of the most important parameters of the invention are the distances between the avalanching drain 104a, the source 104b (i.e. collector of bipolar), the added junction 108 and the bulk connection 106. By controlling these distances, the voltage at the added junction 108 is controlled for a given drain-source voltage. In general, the larger the distance between the added Junction 108 and the bulk connection 106, the higher the voltage at the added junction 108, for given drain-source voltage. Similarly, the smaller the distance between the source 104a and the added j unction 108, the higher the voltage at the added junction, for a given drain-source voltage. The voltage range is typically between 00 and ˜0.7V, with 0.7V being the voltage over bulk-source needed to trigger the driver in bipolar mode. As this triggering should be avoided, all voltages within the well should stay preferably below 0.7V. However, in some cases, a potential transfer circuit and/or a voltage shifter circuit can be added to remove this 0.7V constraint. Even in those cases, typical voltages should not exceed a few volts. The applied distances are governed by the process design rules. Each process has minimum design rules for distances between junctions. For the present invention, typical distances are in the range of 1 to 5 times of the minimum design rules. For example, in a 65 nm CMOS technology, this minimum design rule is in the order of 0.1 um. Note that the present invention is not limited to this distance range.

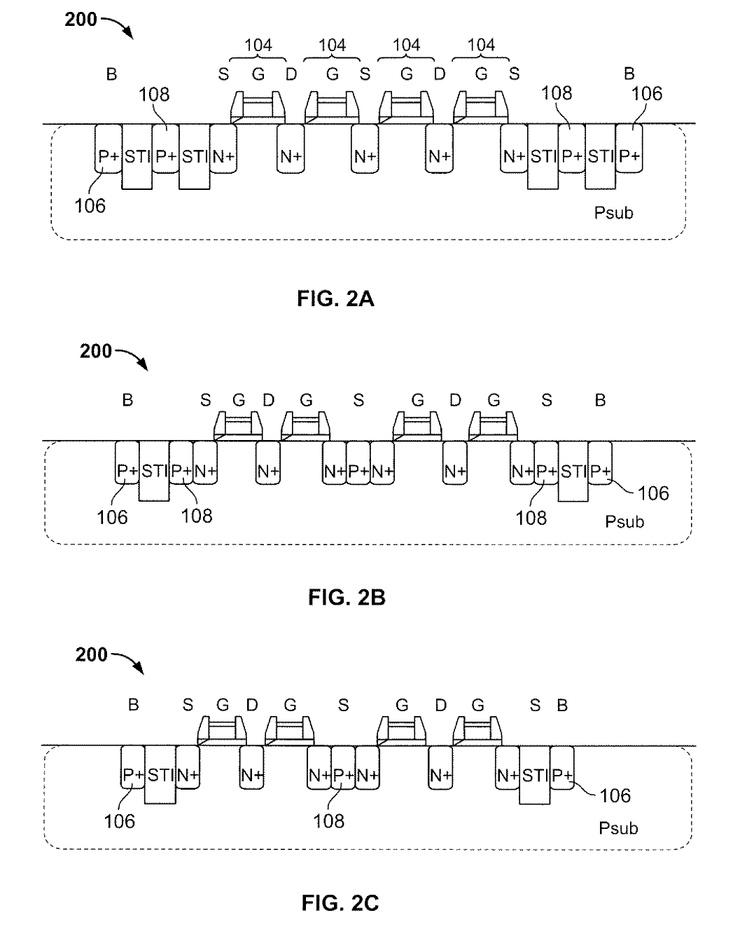

Referring now to FIGS. 2A to 2C, there is illustrated cross-section diagrams of several different implementations of ESD protection circuit 200 of multi finger transistor device 104 with the inclusion of the added junction 108 in accordance with the present invention. In FIG. 2A, there is illustrated a multifinger NMOS device 104 where the junctions 108 are added only at the side of the device. In FIG. 2B, the junctions 108 are added next to each source 104b junction of the transistor 104. In FIG. 2C, the junction 108 is added only at the middle source region 104b of the transistor 104. Note that even though the present invention discloses the implementations of the added junction 108 as illustrated in FIGS. 2A, 2B and 2C, those skilled in the art would appreciate that many other possible implementations of the addition of the junction also exist.

The potential measured by the added junction, 108 is preferably transferred to a switching circuit (described below), which can either draw the full ESD current, or in its turn trigger another switching circuit to draw the full ESD current. To explain the working principle of this embodiment, one must consider that bipolar action of MOS device starts when the well potential locally exceeds the source potential by one diode drop (approximately 0.7V). Typically this is achieved by having an avalanching current, created by a high electric field at the drain, flow through the well resistance, such that the well potential is increased. If too much avalanche current is needed, or if a high avalanche current needs to flow for a significantly long duration, the heating caused by the avalanching will damage the device. Therefore it is important to limit the needed amount of avalanching. By transferring the well potential to the trigger via the added junction 108 of the present invention, it is possible to switch the clamp at a lower voltage. Lowering this voltage also means lowering the electric field at the drain, and thus to have less heat generation.

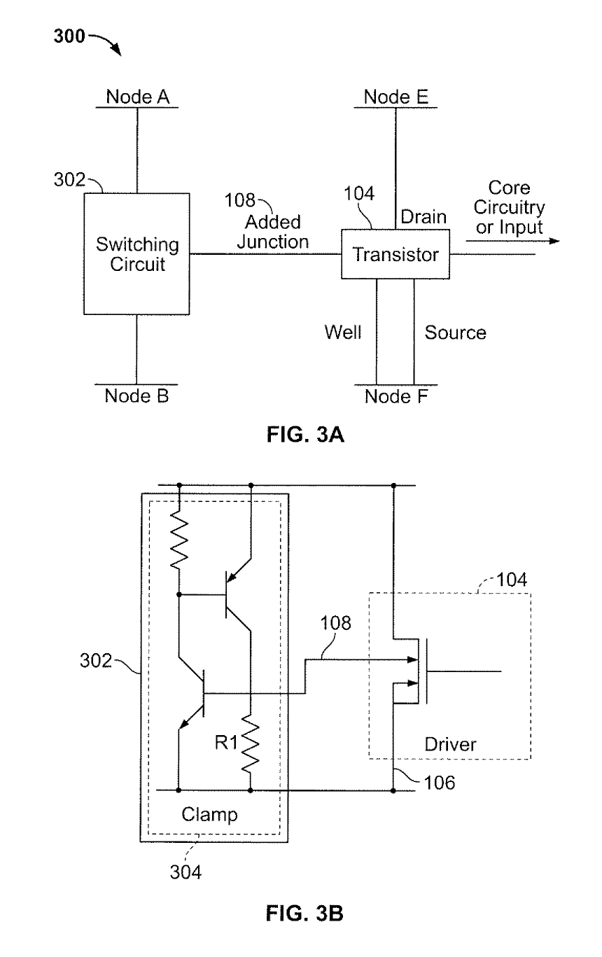

FIG. 3A illustrates a schematic representation of a block diagram 300 using ESD protective scheme 100 illustrated in FIGS. 1A and 1B of the present invention with addition of the switching circuit 302 in parallel to the transistor 104, as shown. As discussed above, the voltage potential measured by the added junction 108 is preferably transferred to a switching circuit 302 which can either draw the full ESD current, or in its turn trigger another switching circuit to draw the full ESD current. In case two switching circuits are used, the first one is called the ‘trigger’ while, the second one is called the ‘Clamp’. In case only one switching circuit is used, this device is called the ‘clamp’. Both trigger and/or clamp can consist of one or multiple devices. These devices can be amongst others one or more diodes, SCRs, Transistors (MOS, Bipolar or any other type), Capacitances, Resistors, Inductors or any combination of these elements.

Note that in FIG. 3A, nodes A and F can be separate or shared. Likewise, nodes B and F can be separate or shared. In most implementations, node E being the output, nodes B and F being the ground and nodes A and E being either output or Vdd. In another implementation when the transistor 104 is a PMOS, nodes A and E being Vdd, node F being output and nodes B and F being either output or ground.

Referring to FIG. 3B, there is shown a schematic circuitry of the block diagram 300 according to one alternate embodiment of the present invention. In this embodiment, the switching circuit 302 preferably includes only a SCR clamp 304 which fully draws the ESD current upon transfer of the voltage potential by the added junction 108. The voltage needed at the G1 node to trigger the SCR 304 is ˜0.7V, which is roughly the same as the voltage needed to trigger driver 104 in bipolar node. Additional implementations of the switching circuit 302 are described below.

Referring to FIG. 3C, there is shown a schematic circuitry of the block diagram 300 according to another alternate embodiment of the present invention. As mentioned above, switching circuits 302 preferably comprising of a SCR clamp 304 and a trigger device 306, in this example an NMOS 306, both connected in parallel to the driver 104. Specifically, the base of the trigger NMOS 306 is connected to the added junction 108 of the transistor 104 as illustrated in FIG. 3C. Note that the transistor 104 is also known as the driver in the present invention due to the fact that the behavior of the transistor can be used to drive other elements of the circuit. It is important to note that the potential at the added junction 108 is assumed to be equal to the potential at the source 104c of the driver NMOS 104. This is justified by the fact that for the preferred embodiment, the added junction 108 and source 104c are drawn as close together as allowed in the process.

The working principle of the circuit of FIG. 3C is described herein. Initially, when the ESD event hits an output pad (Node E), the voltage of the drain of the driver 104 rises, causing avalanching at the drain-source junction. This avalanche current causes the well potential of the transistor driver 104 to increase. As soon as this value reaches the threshold voltage, Vth of the trigger NMOS 306, this trigger NMOS 306 switches to its ‘ON’ state, thus drawing ESD current. This ESD current will trigger the SCR clamp 304. The threshold voltage is the minimum voltage between gate and source where the transistor (NMOS or PMOS) turns in a conductive state. As this clamp 304 is triggered, the ESD current is shunted away. Note that if the threshold voltage of the trigger NMOS 306 is below 0.7V, this switching still occurs before the driver 104 goes into bipolar mode. Also note that the SCR 304 remains in the “ON” state and continues to draw ESD current even if potential drops below the threshold voltage of the trigger NMOS 306. If the threshold voltage Vth of trigger NMOS 306 is above 0.7V, the driver 104 will go in bipolar mode. In that case, the driver must be made robust against triggering, using known techniques such as drain ballasting. Thus, the threshold voltage must be low enough, such that the protection can trigger before failure of the driver 104 occurs.

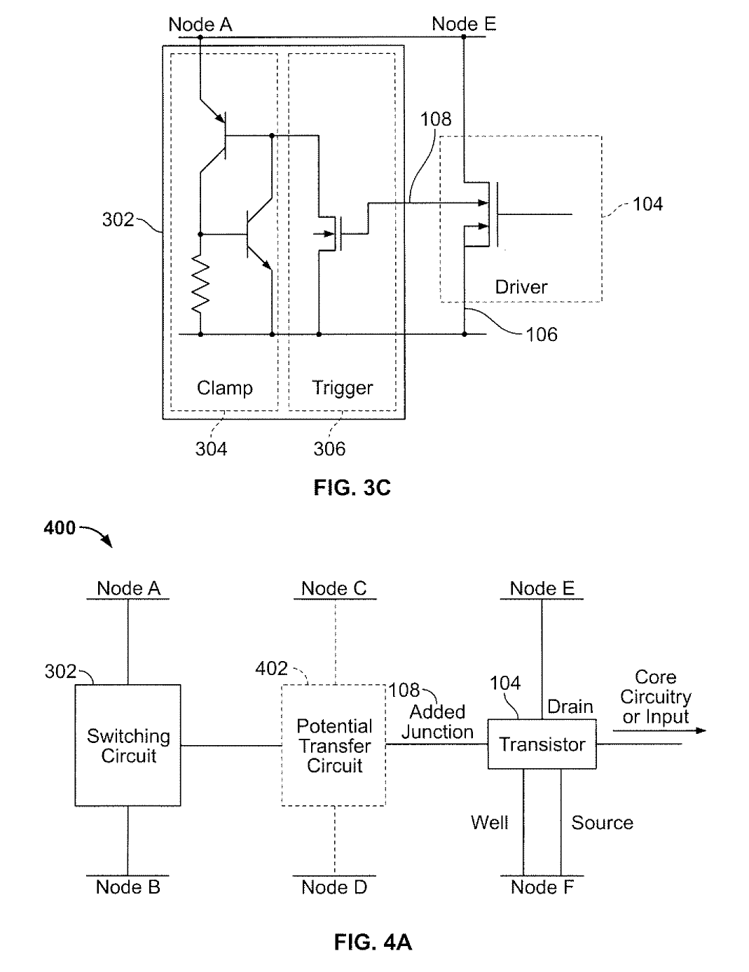

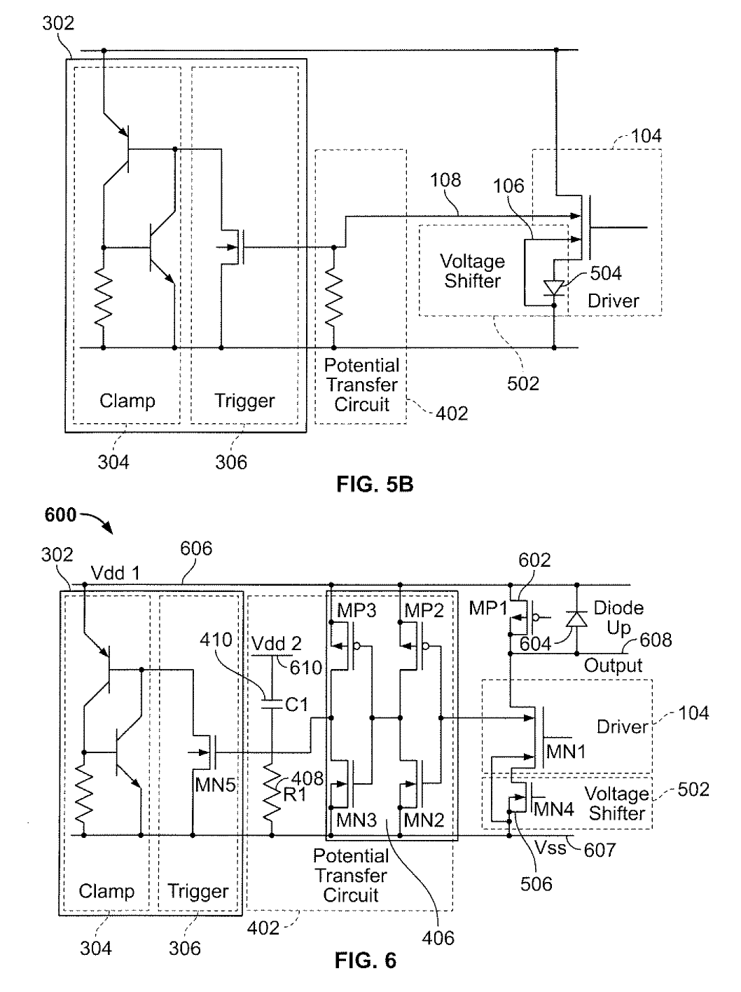

FIG. 4A illustrates a block diagram 400 using ESD protective scheme 300 illustrated in FIG. 3A of the present invention with addition of the potential transfer circuit 402 preferably positioned in parallel between the driver 104 and the switching circuit 302, as shown. The potential transfer circuit 402 preferably transfers the potential of the driver 104 to the switching circuit 302. The potential transfer circuit 402 transfer circuit 402 can serve many different functions. One of the functions is to reduce the possibility of triggering the ESD protection in a normal operation due to noise in the substrate 102 of the driver 104. Implementations for this case include adding a resistor (as described with reference to FIG. 4B below), adding a capacitance between the added Junction and a power line, or adding one or multiple inverter stages. The other function of the potential transfer circuit 402 is to amplify the voltage potential of the driver 104 to help the trigger circuit 306 to trigger. In this case the potential transfer circuit 402 would preferably comprise an amplifier circuit which can be designed such that the voltage potential transferred to the trigger circuit 306 can be controlled (increase or decrease the potential). Implementations for this case include adding inverter stages, as described with reference to FIG. 6 below. Note, that the voltage at the output of the potential transfer circuit 402 can be different than the voltage at its input.

Note in FIG. 4A, nodes A, C and E can be separate or shared. Likewise, nodes B, D and F can be separate or shared. In most implementations, node E being the output, nodes B, D and F being the ground and nodes A, C and E being either output or Vdd. In another implementation when the transistor 104 is a PMOS, nodes A, C and E being Vdd, node F being output and nodes B and D being either output or ground.

Referring to FIG. 4B of the present invention, there is illustrated a schematic circuitry of the block diagram 400 according to one alternate embodiment of the present invention. In this embodiment, the potential transfer circuit 402 preferably includes a resistor 404. Specifically, the gate of the trigger 306 is connected to the resistor 404 which is in turn connected to the added junction 108 of the driver 104. This resistor 404 is in parallel to the substrate resistance of the ground connection of driver 104, and therefore allows calculating the amount of avalanching current in driver 104 needed to trigger the trigger NMOS 306. Note that the potential transfer circuit 402 as illustrated in FIG. 4 preferably comprises a resistor 404, the invention is not limited to any specific kind of impedance element, being active or passive such as diodes, MOS devices, well resistances, capacitors, SCRs, inductors, short, etc.

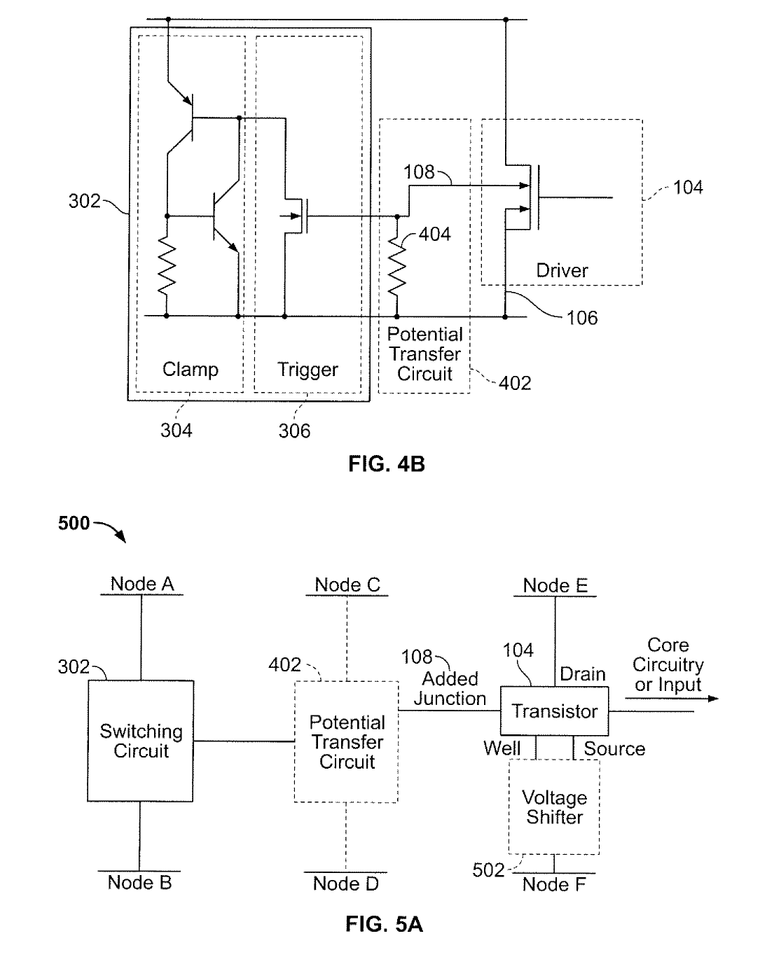

FIG. 5A illustrates a block diagram 500 using ESD protective scheme 300 illustrated in FIG. 4A of the present invention with addition of a voltage shifter 502 preferably positioned in series with the transistor driver 104 as shown. A voltage shifter 502 preferably means any circuit or layout change which functions to control the needed voltage between well/substrate 102 and the source 104b to trigger the transistor driver 104 into bipolar mode. As discussed above, nodes A, C and E can be separate or shared. Likewise, nodes B, D and F can be separate or shared. In most implementations, node E being the output, nodes B, D and F being the ground and nodes A, C and E being either output or Vdd. In another implementation when the transistor 104 is a PMOS, nodes A, C and E being Vdd, node F being output and nodes B and D being either output or ground.

Referring to FIG. 5B, there is shown a schematic circuitry of the block diagram 500 according to one alternate embodiment of the present invention. In this embodiment, the exemplary implementation of the voltage shifter 502 is a diode, 504 with the anode of the diode 504 being coupled to the source 104b of the driver 104, and the cathode of the diode 504 coupled to the bulk 106 and ground. In other implementations, this diode 504 can be replaced by a transistor which also can then also serve dedicated function during normal operation as will be described in greater detail with reference to FIG. 6 below.

Referring to FIG. 6 there is shown a schematic circuitry 600 of the block diagram 500 with additional elements according to another alternate embodiment of the present invention. In this embodiment, the exemplary implementation of the voltage shifter 502 is a transistor MN4 506; and the potential transfer circuit 402 is an inverter stage circuit 406 with a combination of resistor R1 408 in series with capacitor C1 410 connected to a voltage Vdd2 610 as shown. The circuit 600 also comprises a PMOS transistor 602 MP1 connected to the drain NMOS transistor MN1 of the driver 104. The circuit 600 further comprises a diode up 604 connected in parallel with MP1 602 and further connected to a voltage Vdd1 606 as shown in FIG. 6. Note that Vdd1 606 and Vdd2 610 are any node which has a constant potential during normal operation. Vss 607 as shown in the circuit 600 is preferably ground. Additionally, an output 608 of the circuitry 600 consists of PMOS transistor MP1 602 and the NMOS transistor MN1 104. The circuit 600 illustrates a more complicated connection, and is not meant to limit the invention in any way. As discussed above, the purpose of the circuit 600 is to amplify the voltage potential of the driver 104 to help the trigger circuit 306 to trigger by designing the potential transfer circuit 402 to include the inverter stages such that the voltage potential transferred to the trigger circuit 306 can be controlled (increase or decrease the potential). This creates a margin for the trigger circuit 306, thus allowing the threshold voltage of the trigger NMOS 306 to be higher. The working principle of this embodiment is described herein below.

Initially, when the voltage at the output 608 rises due to ESD, the voltage at Vdd1 606 also rises with ˜0.7V or less, being the built-in voltage of the diode up 608. As the voltage over MN1 104 rises, the potential in the well/substrate 102 of MN1 104 also increases. At a certain moment, the threshold voltage of M2 of the inverter stage circuit 604 is reached. Due to voltage potential of the MN4 506, which acts a voltage shifter, the threshold voltage of MN2 can reach higher than 0.7V. Note that MN4 506 can have a dedicated function, i.e. can switch, under normal condition of the circuit. This is called a cascaded design well known to one skilled in the art. When MN2 switches to “ON”, MP2 switches to “OFF”, because the well potential of MN1 104 is larger than the threshold voltage of MP2. This switching of MP2 and MN2 causes MP3 to switch to “ON”. Therefore, current is injected from the Vdd2 line 610 though MP2 and through R1 408, building up voltage over the gate of MN5 of trigger 306. Note that at this time MN3 is in “OFF” state. As MN5 306 is turned on, it triggers the SCR clamp 304. The ESD current can now be safely shunted through diode up 604 and the SCR clamp 304. Note that this clamp 304 can also be preferably used as a power clamp (i.e. Vdd-Vss protection), if a dedicated trigger scheme is added. Also the clamp 304 and the trigger 306 can now easily be shared over multiple output ads (not shown). Additionally, part of or the entire potential transfer circuit 604 can be shared over multiple output pads. Capacitance C1 410 preferably functions to stabilize the gate of MN5 304 during normal operation to avoid false triggering due to substrate current in the well of MN1 104.

Although various embodiments that incorporate the teachings of the present invention have been shown and described in detail herein, those skilled in the art can readily devise many other varied embodiments that still incorporate these teachings without departing from the spirit and the scope of the invention.

1. An electrostatic discharge (ESD) protection circuit, said circuit comprising:
a substrate region comprising a lightly doped region of a first conductivity type;
at least one interleaved finger formed substantially on said substrate region; said at least one interleaved finger comprising at least one source region of a second conductivity type, at least one drain region of the second conductivity type and at least one gate region formed over a channel region disposed between said source and drain regions; and
at least one highly doped junction of the first conductivity type formed substantially adjacent to the source region of the at least one said interleaved finger, wherein said at least one highly doped junction being operative to measure potential of the substrate region.

2. The ESD protection circuit of claim 1 wherein said highly doped junction of the first conductivity type is electrically isolated from the at least one source region.

3. The ESD protection circuit of claim 1 further comprising a bulk connection placed in the source region of said interleaved finger, wherein said bulk connection is electrically isolated from said highly doped junction of the first conductivity type.

4. The ESD protection circuit of claim 3 wherein said electrical isolation is formed using one of trench isolation, field oxide, poly gate, salicide block or silicide block.

5. The ESD protection circuit of claim 1 wherein said first conductivity type comprises one of n or p conductivity types.

6. The ESD protection circuit of claim 4 wherein said second conductivity type comprises other of the n or p conductivity types.

7. An integrated circuit for providing ESD protection, said circuit comprising:
a MOS transistor comprising a substrate region comprising a lightly doped region of a first conductivity type, at least one interleaved finger formed substantially on said substrate region, said at least one interleaved finger comprising at least one source region of a second conductivity type, at least one drain region of the second conductivity type and at least one gate region formed over a channel region disposed between said source and drain regions, and at least one highly doped junction of the first conductivity type for measuring voltage potential of the substrate region, wherein said at least one highly doped junction formed substantially adjacent to the source region of the at least one said interleaved finger, said at least one highly doped junction function to measure voltage potential of the substrate region; and
a switching circuit connected to the at least one highly doped junction to receive said voltage potential for triggering.

8. The integrated circuit of claim 7 wherein said highly doped junction of the first conductivity type is electrically isolated from the at least one source region.

9. The integrated circuit of claim 8 wherein said electrical isolation is formed using one of trench isolation, field oxide, poly gate, salicide block or silicide block.

10. The integrated circuit of claim 7 further comprising a bulk connection placed in the source region of said interleaved finger, wherein said bulk connection is electrically isolated from said highly doped Junction of the first conductivity type.

11. The integrated circuit of claim 10 wherein said electrical isolation is formed using one of trench isolation, field oxide, poly gate, salicide block or silicide block.

12. The integrated circuit of claim 10 wherein distance between the at least one highly doped junction and the bulk connection is controlled to control the voltage potential of the substrate region.

13. The integrated circuit of circuit of claim 7 wherein said switching circuit is subject to triggering when said voltage potential is above a threshold voltage of the switching circuit.

14. The integrated circuit of claim 7 wherein said switching circuit comprise an SCR clamp.

15. The integrated circuit of claim 7 wherein said switching circuit comprise a combination of an SCR clamp and a trigger element, wherein said trigger element is coupled to the at least one highly doped junction.

16. The integrated circuit of claim 15 wherein said trigger element comprise at least one of a transistor, wherein gate of the transistor is coupled to at the at least one highly doped junction.

17. The integrated circuit of claim 15 wherein said trigger element comprise at least one of an SCR and a diode.

18. The integrated circuit of claim 7 further comprises a potential transfer circuit coupled between the highly doped region and the switching circuit.

19. The integrated circuit of claim 18 wherein said potential transfer circuit comprise at least one of a resistor, an inductor, transistor, SCR or a capacitor.

20. The integrated circuit of claim 18 wherein said potential transfer circuit comprise at least one inverter circuit.

21. The integrated circuit of claim 10 further comprises a voltage shifter coupled to the hulk connection and the source.

22. The integrated circuit of claim 21 wherein said voltage shifter comprise a diode.

23. The integrated circuit of claim 21 wherein said voltage shifter comprise a transistor.

24. The integrated circuit of claim 7 wherein said first conductivity type comprises one of n or p conductivity types.

25. The integrated circuit of claim 7 wherein said second conductivity type comprises other of the n or p conductivity types
